(19) United States
(12) Patent Application Publication
(10) Pub. No.: US 2019/0088868 A1
(43) Pub. Date: Mar. 21, 2019

(54) MEMORY DEVICE

(71) Applicant: KABUSHIKI KAISHA TOSHIBA, Minato-ku (JP)

(72) Inventor: Yoshiki KAMATA, Tsukuba (JP)

(73) Assignee: KABUSHIKI KAISHA TOSHIBA, Minato-ku (JP)

(21) Appl. No.: 15/908,145

(22) Filed: Feb. 28, 2018

(30) Foreign Application Priority Data
Sep. 20, 2017 (JP) 2017-180741

(51) Int. Cl. H01L 45/00

(52) U.S. Cl. CPC H01L 45/06; H01L 45/144; H01L 45/1253

(57) ABSTRACT

According to one embodiment, a memory device includes a nonvolatile memory element having a first resistance state and a second resistance state having a higher resistance than the first resistance state, wherein the nonvolatile memory element includes a first electrode, a second electrode, and a stacked structure located between the first electrode and the second electrode, and the stacked structure includes a first antimony tellurium layer, a first germanium tellurium layer, and an insulating layer spaced apart from the first electrode and the second electrode.

### CROSS-REFERENCE TO RELATED APPLICATIONS

This application is based upon and claims the benefit of priority from Japanese Patent Application No. 2017-180741, filed Sep. 20, 2017, the entire contents of which are incorporated herein by reference.

### FIELD

Embodiments described herein relate generally to a memory device.

### BACKGROUND

There has been proposed a memory device (semiconductor integrated circuit device) in which a phase change element which is a nonvolatile memory element and a transistor (or a selector) are integrated on a semiconductor substrate. Such a memory device having phase change elements is usually called PCM (an acronym of Phase Change Memory) or PRAM (an acronym of Phase-change Random Access Memory). In PCM (PRAM), a voltage is applied to a phase change element to flow a current, thereby generating heat in the phase change element so as to change the crystal state.

However, PCM (PRAM) has a problem that it is difficult to efficiently use heat generated in a nonvolatile memory element. Specifically, GeSbTe alloy is usually used for PCM, and resistance of a memory cell is changed by changing crystallinity of a GeSbTe layer on an electrode to crystalline and amorphous, and electric power consumed as the three-dimensional movement of atoms, that is, entropy loss is large. Thus, in order to limit the movement of Ge atoms, which is considered to be a factor of resistance change, not in any three-dimensional direction such as PCM but in a certain fixed direction, a superlattice-type phase change memory (superlattice memory, interfacial PCM, iPCM) in which GeTe and Sb₂Te₃ contained in a PCM element are stacked in the form of layers has been proposed. For low power consumption operation and low current operation, a memory device having a nonvolatile memory element capable of performing more efficient rewriting operation than a current iPCM element is desired.

### BRIEF DESCRIPTION OF THE DRAWINGS

FIG. 1 is a diagram schematically showing a configuration of a nonvolatile memory element in a memory device according to a first embodiment;

FIG. 2 is a diagram schematically showing a crystal structure of antimony tellurium;

FIG. 3 is a diagram schematically showing an energy band structure of the nonvolatile memory element according to the first embodiment;

FIG. 4 is a diagram schematically showing a configuration of a first modification example of the nonvolatile memory element in the memory device of the first embodiment;

FIG. 5 is a diagram schematically showing a configuration of a second modification example of the nonvolatile memory element in the memory device of the first embodiment;

FIG. 6 is a diagram schematically showing a configuration of a third modification example of the nonvolatile memory element in the memory device of the first embodiment;

FIG. 7 is a diagram schematically showing a configuration of a nonvolatile memory element in a memory device according to a second embodiment;

FIG. 8 is a diagram schematically showing an energy band structure of the nonvolatile memory element according to the second embodiment; and

FIG. 9 is a diagram schematically showing a configuration of a modification example of the nonvolatile memory element in the memory device of the second embodiment.

### DETAILED DESCRIPTION

In general, according to one embodiment, a memory device includes a nonvolatile memory element having a first resistance state and a second resistance state having a higher resistance than the first resistance state, wherein the nonvolatile memory element includes a first electrode, a second electrode, and a stacked structure located between the first electrode and the second electrode, and the stacked structure includes a first antimony tellurium layer, a first germanium tellurium layer, and an insulating layer spaced apart from the first electrode and the second electrode.

Hereinafter, embodiments will be described with reference to the drawings.

### Embodiment 1

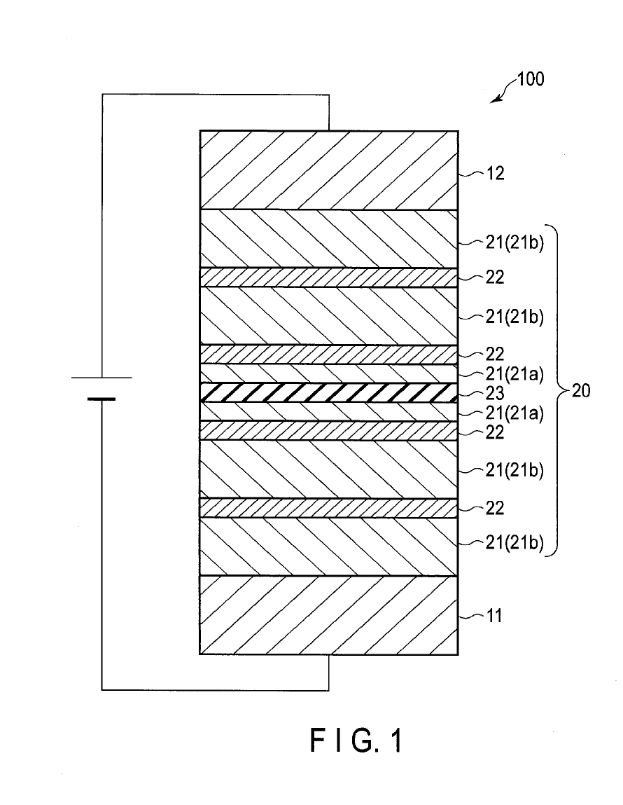

FIG. 1 is a diagram schematically showing a configuration of a nonvolatile memory element in a memory device (semiconductor integrated circuit device) according to the first embodiment.

A nonvolatile memory element 100 is formed on a lower structure (not shown) including a semiconductor substrate, a transistor, wiring, an interlayer insulating film, and so on. The nonvolatile memory element 100 can selectively exhibit one of a low resistance state and a high resistance state and includes an electrode 11, an electrode 12 and a stacked structure 20 located between the electrode 11 and the electrode 12. Voltage is applied to the stacked structure 20 by the electrode 11 and the electrode 12.

The stacked structure 20 includes an antimony tellurium (Sb₂Te₃) crystal layer 21, a germanium tellurium (GeTe) crystal layer 22, and an insulating layer 23 spaced apart from the electrode 11 and the electrode 12. The insulating layer 23 is in contact with the antimony tellurium crystal layer 21 and is located between the germanium tellurium crystal layers 22. In the example shown in FIG. 1, the stacked structure 20 includes six antimony tellurium crystal layers 21, four germanium tellurium crystal layers 22, and one insulating layer 23.

The antimony tellurium crystal layer 21 can be divided into two antimony tellurium crystal layers 21a in contact with the insulating layer 23 and the other four antimony tellurium crystal layers 21b. In other words, the insulating layer 23 is located between the two antimony tellurium crystal lavers 21a and is in contact with the two antimony tellurium crystal layers 21a.

From another point of view, in the example shown in FIG. 1, the stacked structure 20 has as a basic structure of a superlattice structure in which five antimony tellurium crystal layers 21 and four germanium tellurium crystal layers 22 are alternately stacked and has a structure in which one of the antimony tellurium crystal layers 21 sandwiches the insulating layer 23.

It is known that a nonvolatile memory element having a superlattice structure in which antimony tellurium (Sb₂Te₃) and germanium tellurium (GeTe) are alternately stacked selectively exhibits one of the low resistance state and the high resistance state by changing a write signal (such as a magnitude of a write voltage and/or a waveform of the write voltage). Specifically, it is thought that by changing the atomic position of germanium (Ge) in GeTe, one of the low resistance state and the high resistance state is selectively exhibited.

In the present embodiment, as described above, the superlattice structure in which the antimony tellurium (Sb₂Te₃) crystal layers 21 and the germanium tellurium (GeTe) crystal layers 22 are alternately stacked is a basic structure, and the structure is replaced by a structure in which one of the antimony tellurium crystal layers 21 sandwiches the insulating layer 23. Accordingly, the nonvolatile memory element of this embodiment can also realize characteristics similar to those of the nonvolatile memory element having the above-described structure in which antimony tellurium (Sb₂Te₃) and germanium tellurium (GeTe) are alternately stacked. That is, the nonvolatile memory element of this embodiment selectively exhibits one of the low resistance state and the high resistance state by changing the write signal (such as the magnitude of the write voltage and/or the waveform of the write voltage). In other words, in the nonvolatile memory element of this embodiment, the atomic position of germanium (Ge) in the GeTe layer 22 changes according to the write signal, and selectively exhibits one of the low resistance state and the high resistance state.

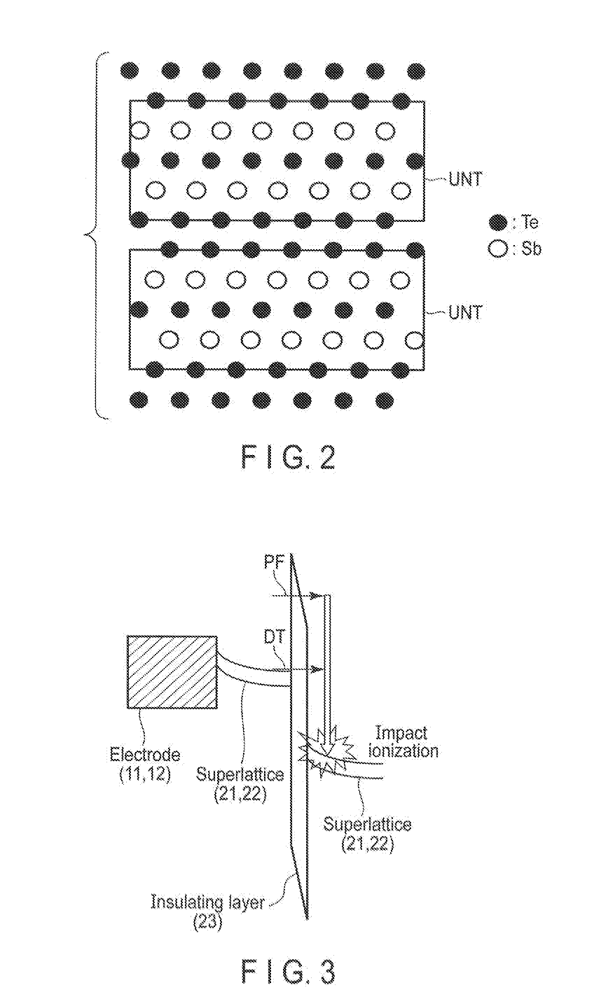

FIG. 2 is a diagram schematically showing a crystal structure of antimony tellurium (Sb₂Te₃). As shown in FIG. 2, Sb₂Te₃ has as a unit structure UNT in which Sb of two atomic layers and Te of three atomic layers are alternately provided. Each of the antimony tellurium crystal layers 21 shown in FIG. 1 has a structure formed with the single unit structure UNT or a structure in which a plurality of the unit structures UNT are stacked. In this embodiment, each of the antimony tellurium crystal layers 21 is formed of one or a plurality of unit structures UNT.

As described above, in the germanium tellurium (GeTe) crystal layer 22, the atomic position of germanium (Ge) in the GeTe layer 22 is changed by changing the write signal (such as the magnitude of the write voltage and/or the waveform of the write voltage), and one of the low resistance state and the high resistance state is selectively exhibited.

The insulating layer 23 is formed of a two-dimensional layered material. As the two-dimensional layered material constituting the insulating layer 23, a multilayer two-dimensional material formed of two or more layers of two-dimensional material may be used, or a single layered two-dimensional material formed of one layer of two-dimensional material may be used. In this embodiment, a multilayer two-dimensional material is used. Specifically, as the two-dimensional layered material, a similar compound h-BN (hexagonal-boron nitride) or TMD (transition metal dichalcogenide) of a monoatomic layered material or the like can be used. As TMD, MX₂ (M=Ti, Zr, Hf, V, Nb, Ta, Mo, or W; X=S, Se, or Te) or the like can be used. In addition, it is possible to similarly use a Group 13 chalcogenide such as GaS, GaSe, GaTe, or InSe, a Group 14 chalcogenide such as GeS, SnS2, SnSe2, or PbO, a divalent metal hydroxide M(OH)₂ (M=Mg, Ca, Mn, Fe, Co, Ni, Cu, Cd, or the like), titanium oxide (Ti_{0.91}O₂, Ti_{0.87}O₂, Ti₄O₉, Ti₅O₁₁, Ti_{0.8}Co_{0.2}O₂, Ti_{0.6}Fe_{0.4}0₂, Ti_{(5.2-2x)/6}Mn_{x/2}O₂ (0≤x≤0.4)) as a layered oxide, tantalum oxide (TaO₆), manganese oxide (MnO₆), cobalt oxide (CoO₂), molybdenum oxide (MoO₂), tungsten oxide (W₂O₇), niobium oxide (Nb₆O₁₇, Nb₃O₈), ruthenium oxide (RuO_{2.1}, RuO₂), and the like.

In the above embodiment, iPCM is desirable in which an antimony tellurium (Sb₂Te₃) layer and a germanium tellurium (GeTe) layer in the low resistance state and the high resistance state are both crystals. In a case of a super lattice like (SLL) in which the germanium telluride (GeTe) layer in the low resistance state and the high resistance state is crystalline and amorphous, it is effective that the insulating layer 23 intervenes.

In a case of fabricating a memory element using layered materials such as iPCM and SLL-PCM, film peeling becomes a problem. Although a Te//Te-gap, that is, a van der Waals gap is formed between Sb₂Te₃//Sb₂Te₃ and between Sb2Te3//GeTe, the van der Waals gap is very likely to be peeled off. For example, although graphenes are bonded to each other with the van der Waals gap to form graphite, graphene can be easily peeled off from graphite by tape. Likewise, in general a two-dimensional layered material stacked with the van der Waals gap is likely to be peeled off, and if the two-dimensional layered material is peeled off, it becomes difficult to fabricate a device in a clean room or the like. Thus, suppression of peeling is one of important issues in device fabrication. A two-dimensional material having polarity is desirable because it has a strong binding force between two-dimensional materials and therefore has a peeling prevention effect, and among the insulating layers 23 described above, a polar substance such as h-BN is desirable.

In this embodiment, a nonvolatile memory element capable of efficiently increasing a current can be obtained by using the stacked structure 100 as described above. The following description is added.

FIG. 3 is a diagram schematically showing an energy band structure of the nonvolatile memory element according to this embodiment.

As shown in FIG. 3, when an insulating layer (corresponding to the insulating layer 23) intervenes in a superlattice structure (corresponding to the antimony tellurium crystal layer 21 and the germanium tellurium crystal layer 22), electrons from an electrode (corresponding to the electrode 11 or 12) pass through the insulating layer (23) by tunneling and thermal excitation. Specifically, the electrons pass through the insulating layer (23) by direct tunneling (DT) and poole frenkel (PF) tunneling or thermal excitation. At this time, when the electrons having passed through the insulating layer (23) fall to the bottom of the energy band, great energy is lost, and impact ionization occurs. This impact ionization produces a large amount of carriers and produces a negative differential resistance called snap back in current sweep I-V measurements. Since current is drastically increased by the carriers produced in large amounts, the write performance of the nonvolatile memory element can be improved. Here, in a case where electrons are injected into the superlattice from the electrode 11 through the insulating layer 23 by PF tunneling and thermal excitation, the larger a conduction band offset (ΔEc) between the electrode 11 and the insulating layer 23, the larger the lost energy; therefore, impact ionization efficiency is large, and it is effective.

That is, in a case where a conduction band offset ΔEc between the insulating layer 23 and a layer which injects electrons through the insulating layer 23 is greater than zero, an energy loss caused by thermal excitation or PF tunneling is larger than a case where the insulating layer 23 is not provided, and thus impact ionization efficiency is high. Accordingly, it can be said that the insulating layer 23 is a material with the ΔEc greater than zero.

In the nonvolatile memory element according to this embodiment, since the insulating layer 23 formed of the two-dimensional layered material is provided in the stacked structure 100, it is possible to efficiently use heat for the following reason.

Since the two-dimensional layered material has a layered structure, thermal conductivity in a direction perpendicular to the layer is low. That is, the two-dimensional layered material has high heat insulating properties. Particularly, when a multilayer two-dimensional material is used as the two-dimensional layered material, a van der Waals gap exists between two-dimensional materials, so that extremely high heat insulating properties can be obtained. For these reasons, conduction of generated heat to the outside can be efficiently suppressed by using the two-dimensional layered material. Accordingly, the nonvolatile memory element according to this embodiment can efficiently use the generated heat, so that the write performance of the nonvolatile memory element can be improved.

As described above, in this embodiment, it is possible to obtain a memory device having a nonvolatile memory element capable of performing an efficient operation.

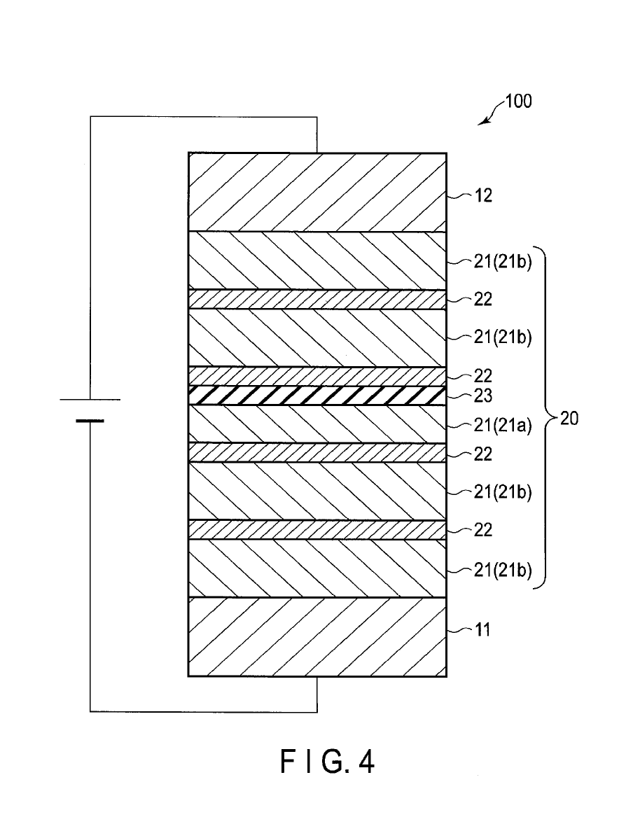

FIG. 4 is a diagram schematically showing a configuration of a first modification example of the nonvolatile memory element in the memory device of this embodiment. Since the basic matters are the same as those of the above embodiment, the explanations of matters that are described in the above embodiment are omitted.

In the embodiment described above, the insulating layer 23 is located between the two antimony tellurium crystal layers 21a and is in contact with the two antimony tellurium crystal layers 21a. However, in this modification example, the insulating layer 23 is located between the antimony tellurium crystal layer 21a and the germanium tellurium crystal layer 22 and is in contact with the antimony tellurium crystal layer 21a and the germanium tellurium crystal layer 22.

Also in this modification example, as in the above embodiment, a nonvolatile memory element capable of performing an efficient operation can be obtained, and the write performance of the nonvolatile memory element can be improved.

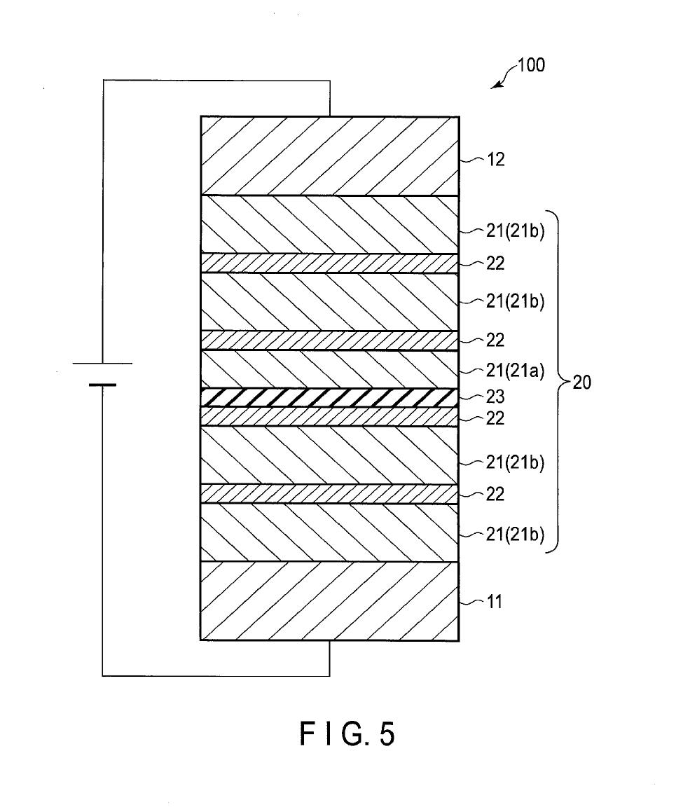

FIG. 5 is a diagram schematically showing a configuration of a second modification example of the nonvolatile memory element in the memory device of this embodiment. Since the basic matters are the same as those of the above embodiment, the explanations of matters that are described in the above embodiment are omitted.

Also in this modification example, as in the first modification example described above, the insulating layer 23 is located between the antimony tellurium crystal layer 21a and the germanium tellurium crystal layer 22, and is in contact with the antimony tellurium crystal layer 21a and the germanium tellurium crystal layer 22. However, in the first modification example described above, the insulating layer 23 is in contact with the upper surface of the antimony tellurium crystal layer 21a, and meanwhile, in this modification example, the insulating layer 23 is in contact with a lower surface of the antimony tellurium crystal layer 21a.

Also in this modification example, as in the above embodiment, a nonvolatile memory element capable of performing an efficient operation can be obtained, and the write performance of the nonvolatile memory element can be improved.

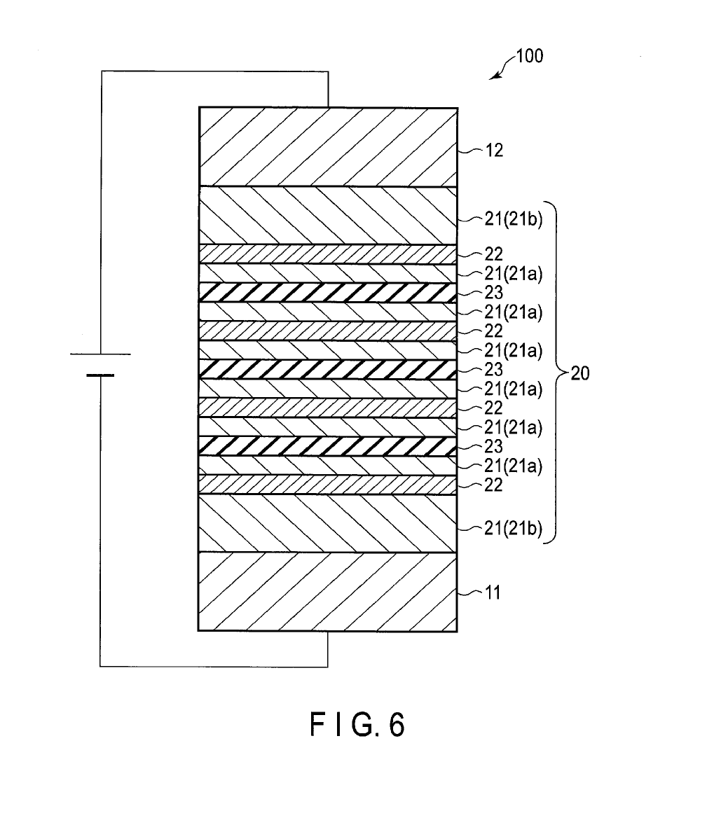

FIG. 6 is a diagram schematically showing a configuration of a third modification example of the nonvolatile memory element in the memory device of this embodiment. Since the basic matters are the same as those of the above embodiment, the explanations of matters that are described in the above embodiment are omitted.

In this modification example, the stacked structure 100 includes a plurality of the insulating layers 23. As in the embodiment described above, each of the insulating layers 23 may be located between the two antimony tellurium crystal layers 21a and may be in contact with the two antimony tellurium crystal layers 21a. Alternatively, as in the first and second modification examples described above, each of the insulating layers 23 may be located between the antimony tellurium crystal layer 21a and the germanium tellurium crystal layer 22 and may be in contact with the antimony tellurium crystal layer 21a and the germanium tellurium crystal layer 22.

Also in this modification example, as in the above embodiment, a nonvolatile memory element capable of performing an efficient operation can be obtained, and the write performance of the nonvolatile memory element can be improved.

In the above embodiment and the first, second, and third modification examples, although a positive voltage is applied to the upper electrode 12 side, the positive voltage may be applied to the lower electrode 11 side.

In the above embodiment and the first, second, and third modification examples, although the two-dimensional layered material is used as the insulating layer 23, another insulating material may be used as the insulating layer 23. For example, an oxide such as a silicon oxide (SiO₂), an aluminum oxide (Al₂O₃), a titanium oxide (TiO₂), a zirconium oxide (ZrO₂), a hafnium oxide (HfO₂), a germanium oxide (GeO₂), or a tantalum oxide (Ta₂O₅), a nitride such as silicon nitride (Si₃N₄) or aluminum nitride (AlN), or an oxynitride such as silicon oxynitride (SiON), aluminum oxynitride (AlON), hafnium oxynitride (HfON), zirconium oxynitride (ZrON), germanium oxynitride (GeON), or tantalum oxynitride (TaON) or the like may be used as the insulating layer 23.

In the case of using the oxides or oxynitrides described above, it is desirable that a physical film thickness is not more than 3 nm in order to cause a tunneling phenomenon such as DT or PF at low voltage.

### Embodiment 2

Next, a memory device (semiconductor integrated circuit device) according to the second embodiment will be described. Since the basic matters are the same as those of the first embodiment, the explanations of matters that are described in the first embodiment are omitted.

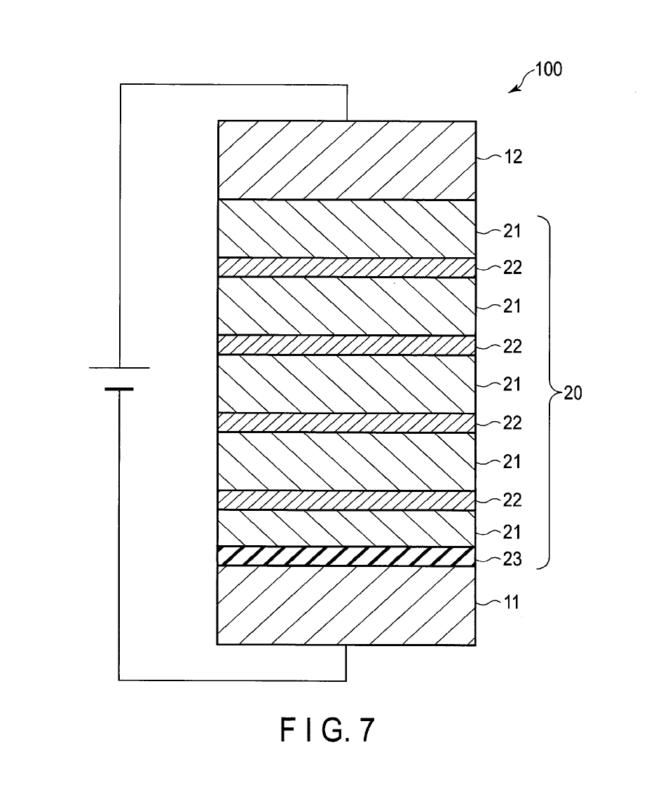

FIG. 7 is a diagram schematically showing a configuration of a nonvolatile memory element in the memory device according to the second embodiment. Similarly to the nonvolatile memory element 100 of the first embodiment, the nonvolatile memory element 100 of this embodiment includes an electrode 11, an electrode 12, and a stacked structure 20 located between the electrode 11 and the electrode 12.

The stacked structure 20 includes an antimony tellurium (Sb₂Te₃) crystal layer 21, a germanium tellurium (GeTe) crystal layer 22, and an insulating layer 23 which is in contact with one of the electrode 11 and the electrode 12 and is formed of a two-dimensional layered material. The insulating layer 23 is preferably in contact with the antimony tellurium crystal layer 21.

As the two-dimensional layered material constituting the insulating layer 23, a multilayer two-dimensional material formed of two or more layers of two-dimensional material may be used, or a single layered two-dimensional material formed of one layer of two-dimensional material may be used. In this embodiment, a multilayer two-dimensional layered material is used. Specifically, as the two-dimensional layered material, a similar compound h-EN (hexagonal-boron nitride) or TMD (transition metal dichalcogenide) of a monoatomic layered material or the like can be used. As TMD, MX₂ (M=Ti, Zr, Hf, V, Nb, Ta, Mo, or W; X═S, Se, or Te) or the like can be used. In addition, it is possible to similarly use a Group 13 chalcogenide such as GaS, GaSe, GaTe, or InSe, a Group 14 chalcogenide such as GeS, SnS₂, SnSe₂, or PbO, a divalent metal hydroxide M(OH)₂ (M=Mg, Ca, Mn, Fe, Co, Ni, Cu, Cd, or the like), layered oxide such as titanium oxide (Ti_{0.91}O₂, Ti_{0.87}O₂, Ti₄O₉, Ti₅O₁₁, Ti_{0.8}CoO_{0.2}O₂, Ti_{0.6}Fe_{0.4}O₂, Ti_{(5.2-2x)/6}Mn_{x/2}O₂ (0≤x≤0.4)), tantalum oxide (TaO₆), manganese oxide (MnO₆), cobalt oxide (CoO₂), molybdenum oxide (MoO₂), tungsten oxide (W₂O₇), niobium oxide (Nb₆O₁₇, Nb₃O₈), ruthenium oxide (RuO_{2.1}, RuO₂), and the like.

In a case of fabricating a memory element using layered materials such as iPCM and super lattice like (SLL)-PCM, film peeling becomes a problem. Although a Te//Te-gap, that is, a van der Waals gap is formed between Sb₂Te₃//Sb₂Te₃ and between Sb₂Te₃//GeTe, the van der Waals gap is very likely to be peeled off. For example, although graphenes are bonded to each other with the van der Waals gap to form graphite, graphene can be easily peeled off from graphite by tape. Likewise, in general a two-dimensional layered material stacked with the van der Waals gap is likely to be peeled off, and if the two-dimensional layered material is peeled off, it becomes difficult to fabricate a device in a clean room or the like. Thus, suppression of peeling is one of important issues. A two-dimensional material having polarity is desirable because it has a strong binding force between two-dimensional materials and therefore has a peeling prevention effect, and among the materials described above, a polar substance such as h-BN is desirable.

In the nonvolatile memory element 100 of this embodiment similarly to the nonvolatile memory element 100 of the first embodiment, the atomic position of germanium (Ge) in the GeTe layer 22 is changed by changing the write signal (such as the magnitude of the write voltage and/or the waveform of the write voltage), and one of the low resistance state and the high resistance state can be selectively exhibited.

Also in this embodiment, a memory device having a nonvolatile memory element capable of performing an efficient operation can be obtained by the nonvolatile memory element having the stacked structure 100 described above. The following description is added.

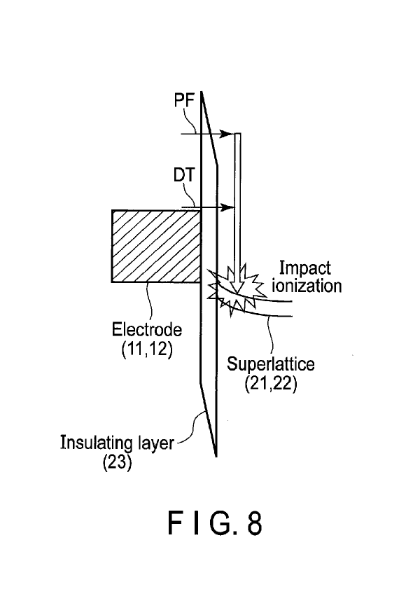

FIG. 8 is a diagram schematically showing an energy band structure of the nonvolatile memory element according to this embodiment.

As shown in FIG. 8, when an insulating layer (corresponding to the insulating layer 23) is interposed between an electrode (corresponding to the electrode 11 or 12) and a superlattice structure (corresponding to the antimony tellurium crystal layer 21 and the germanium tellurium crystal layer 22), electrons from the electrode (corresponding to the electrode 11 or 12) tunnel through the insulating layer (23). As a result, as in the first embodiment, electrons having tunneled through the insulating layer (23) lose large energy, and impact ionization occurs. Since this impact ionization produces a large amount of carriers, the write performance of the nonvolatile memory element can be improved for the same reason as that described in the first embodiment.

In the nonvolatile memory element according to this embodiment, since the insulating layer (23) is interposed between the electrode (11 or 12) and the superlattice structure (21 and 22), heat can be efficiently used for the same reason as that described in the first embodiment. That is, heat conduction to the outside can be efficiently suppressed by high heat insulating properties of a two-dimensional layered material. In particular, heat conduction from the stacked structure 20 to the electrode (11 or 12) can be effectively suppressed. Since the electrode (11 or 12) is connected to an external element outside the nonvolatile memory element, heat is likely to escape to the outside through the electrode. In this embodiment, the insulating layer (23) formed of a two-dimensional layered material is interposed between the electrode (11 or 12) and the superlattice structure (21 and 22), so that it is possible to effectively suppress escape of heat, generated in the nonvolatile memory element, to the outside. Accordingly, in this embodiment, heat generated in the stacked structure 20 can be efficiently used, so that the write performance of the nonvolatile memory element can be improved. As described above, in this embodiment, as in the first embodiment, it is possible to obtain a memory device having a nonvolatile memory element capable of performing an efficient operation.

Further, in this embodiment, the insulating layer (23) formed of a two-dimensional layered material is interposed between the electrode (11 or 12) and the superlattice structure (21 and 22), so that the orientation property (c-axis orientation property) of the antimony tellurium crystal layer 21 can be improved. As already explained (see FIG. 2), the unit structure UNT of antimony tellurium (Sb₂Te₃) has a structure of Te layer/Sb layer/Te layer/Sb layer/Te layer. Te preferentially adheres onto the two-dimensional layered material rather than Sb. Thus, a crystal is grown on the two-dimensional layered material in the order of the Te layer, the Sb layer, the Te layer, the Sb layer and the Te layer, and the orientation property (c-axis orientation property) of the antimony tellurium crystal layer 21 can be improved. Accordingly, the excellent stacked structure 100 can be formed, and a nonvolatile memory element having excellent characteristics can be obtained.

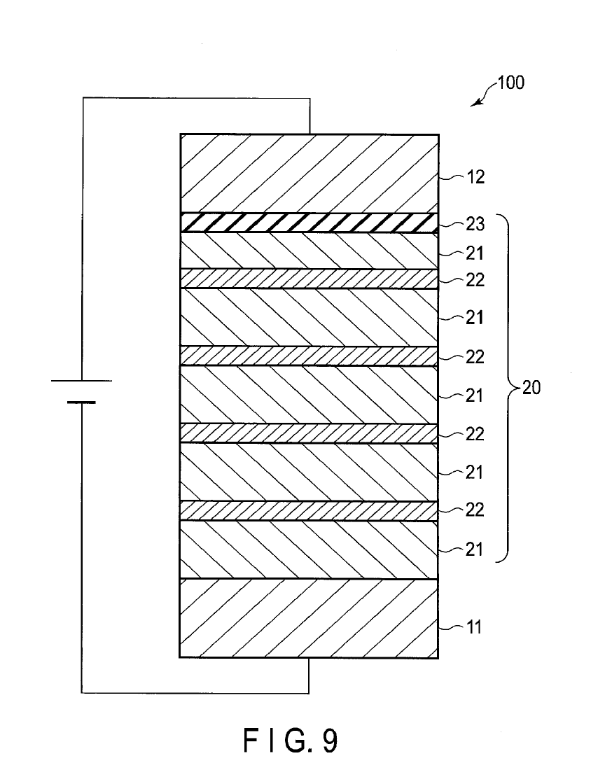

FIG. 9 is a diagram schematically showing a configuration of a modification example of the nonvolatile memory element in the memory device of this embodiment. Since the basic matters are the same as those of the above embodiment, the explanations of matters that are described in the above embodiment are omitted.

In the embodiment described above, the insulating layer 23 is in contact with the lower electrode 11. However, in this modification example, the insulating layer 23 is in contact with the upper electrode 12.

Also in this modification example, as in the above embodiment, a nonvolatile memory element capable of performing an efficient operation can be obtained, and the write performance of the nonvolatile memory element can be improved.

In the above embodiment and modification example, although a positive voltage is applied to the upper electrode 12 side, the positive voltage may be applied to the lower electrode 11 side.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising a nonvolatile memory element having a first resistance state and a second resistance state having a higher resistance than the first resistance state,
wherein the nonvolatile memory element comprises a first electrode, a second electrode, and a stacked structure located between the first electrode and the second electrode, and
the stacked structure comprises a first antimony tellurium layer, a first germanium tellurium layer, and an insulating layer spaced apart from the first electrode and the second electrode.

2. The memory device according to claim 1, wherein the insulating layer is in contact with the first antimony tellurium layer.

3. The memory device according to claim 1, wherein the stacked structure further comprises a second antimony tellurium layer, and
the insulating layer is located between the first antimony tellurium layer and the second antimony tellurium layer and is in contact with the first antimony tellurium layer and the second antimony tellurium layer.

4. The memory device according to claim 1, wherein the insulating layer is located between the first antimony tellurium layer and the first germanium tellurium layer and is in contact with the first antimony tellurium layer and the first uermanium tellurium layer.

5. The memory device according to claim 1, wherein the stacked structure further comprises a second germanium tellurium layer, and
the insulating layer is located between the first germanium tellurium layer and the second germanium tellurium layer.

6. The memory device according to claim 1, wherein the insulating layer is formed of a two-dimensional layered material.

7. The memory device according to claim 1, wherein the nonvolatile memory element exhibits one of the first resistance state and the second resistance state by changing an atomic position of germanium in the first germanium tellurium layer.

8. The memory device according to claim 1, wherein the first antimony tellurium layer has a unit structure in which antimony of two atomic layers and tellurium of three atomic layers are alternately provided.

9. The memory device according to claim 1, wherein the first antimony tellurium layer is a crystal layer.

10. The memory device according to claim 1, wherein the first germanium tellurium layer is a crystal layer.

11. A memory device comprising a nonvolatile memory element having a first resistance state and a second resistance state having a higher resistance than the first resistance state,
wherein the nonvolatile memory element comprises a first electrode, a second electrode, and a stacked structure located between the first electrode and the second electrode, and
the stacked structure comprises an antimony tellurium layer, a germanium tellurium layer, and an insulating layer which is in contact with one of the first electrode and the second electrode and is formed of a two-dimensional layered material.

12. The memory device according to claim 11, wherein the two-dimensional layered material is selected from h-BN (hexagonal-boron nitride), TMD (transition metal dichalcogenide), a Group 13 chalcogenide, a Group 14 chalcogenide, a divalent metal hydroxide, and a layered oxide.

13. The memory device according to claim 11, wherein the insulating layer is in contact with the antimony tellurium layer.

14. The memory device according to claim 11, wherein the nonvolatile memory element exhibits one of the first resistance state and the second resistance state by changing an atomic position of germanium in the germanium tellurium layer.

15. The memory device according to claim 11, wherein the antimony tellurium layer has a unit structure in which antimony of two atomic layers and tellurium of three atomic layers are alternately provided.

16. The memory device according to claim 11, wherein the antimony tellurium layer is a crystal layer.

17. The memory device according to claim 11, wherein the germanium tellurium layer is a crystal layer.
